(19) United States
(12) Patent Application Publication
(10) Pub. No.: US 2005/0105470 A1
(43) Pub. Date: May 19, 2005

(54) Telecommunications network control method and network with said system

(76) Inventors: Francesco Lazzeri, Riva Trigoso (IT); Diego Caviglia, Savona (IT); Giovanni Fiaschi, Genova (IT); Mario Molinari, Genova (IT)

Correspondence Address: KIRSCHSTEIN, OTTINGER, ISRAEL;& SCHIFFMILLER, P.C., 489 FIFTH AVENUE, NEW YORK, NY, 10017, US

(21) Appl. No.: 10/496,822

(22) PCT Filed: Nov. 21, 2002
(86) PCT No.: PCT/IB02/05117

(30) Foreign Application Priority Data
Nov. 30, 2001 (IT) MI2001002536

(51) Int. Cl. G01R 31/08

(52) U.S. Cl. 370/237; 370/238; 370/351

(57) ABSTRACT

A control method or protocol for the control scheme of a connection oriented network such as the automatically switched transport networks (ASTN G.807). Such a protocol provides a set of control functions with the purpose of setting and releasing connections through the transport network. Differently from protocols based on Link State Packet such as ATM, PNNI or MPLS, this protocol is based on a fully shared network database where each node keeps only its own information. This greatly reduces the required computations imposed on the single node.

The present invention relates to a control method or protocol for the control scheme of a connection oriented optical communications network.

Various control protocols have been proposed for the establishment of connection oriented circuits such as PNNI or MPLS. These protocols are based on a Link State Packet in which a routing protocol distributes a complete or hierarchically aggregated description of the entire network to all the nodes and keeps it updated.

While this scheme supplies an efficient operating mode for networks with unrestricted equipment such as for example IP routers of ATM switches, the quantity of information which has to be managed and stored in the network element routing tables increases when the network element connectivity limitations are in place or when a number of different metrics have to be allowed for at the same time to calculate the best path. In this manner the routing protocols become much more complex and carry an increased amount of information at greater frequency with the band width used by transport also increasing and the original benefits of the link state protocol tend to disappear.

Historically, transport networks do not have a shared control scheme and all operations are performed by a centralized network management system. Today with the advent of new types of transport network architecture (ASON, ASTN, GMPLS) the need to spread the routing capability in the network has arisen.

Because of the large number of transport networks installed, a solution impacting as little as possible on the devices already in the field will be considered an optimal solution by the larger part of the market.

In addition, in case of failure a conventional routing protocol requires warning all the equipment in the network or in its area about the unavailability of the resources involved and this happens at a critical moment when the network is trying to restore traffic and other urgent activities have to be performed.

The general purpose of the present invention is to remedy the above mentioned shortcomings by making available an innovative method or protocol for the control of a connection oriented optical network. A network operating in accordance with said method is also provided.

In view of this purpose it was sought to provide in accordance with the present invention a telecommunications network control method for finding optimal paths in the network between the source and destination nodes and establishing connections through said paths and comprising a request step, a response step and a confirmation step. In the request step, messages are propagated over the network to collect information about accumulated cost and other metrics of the possible paths and each node reached by the messages stores the best partial results with the metrics of the result and the preceding hop identifying that path so that knowledge of the network by the node is unnecessary. In accordance with another aspect of this method the partial results are updated upon reception of a new message indicating a still better path. An updating on a node is propagated to all the possible neighboring nodes with some exclusions and the optimal path is chosen in the request step and is stored in the network with hop by hop sharing information in the nodes which it traverses.

In accordance with another aspect of the present invention, starting from the destination node, a free channel is chosen towards the node indicated in a variable previous hop. Then there is the response step in which if the free channel is found a matrix connection is established and the process is propagated with a response message to the preceding node of the hop.

In accordance with another aspect of the present invention, when the response message believed to be the last reaches the source node and all the matrix connections are created the circuit is established and a Confirm message is propagated from the source node to the destination node to complete the confirmation step.

Lastly, if a free channel is not found, an error message is sent to the source node to inform that the process failed and a cancellation procedure is started towards the destination node to cancel matrix connections already established.

Again in accordance with the principles of the present invention it was also sought to realize a telecommunications network in accordance with the claimed method.

To clarify the explanation of the innovative principles of the present invention and its advantages compared with the prior art there is described below with the aid of the annexed drawings a possible embodiment thereof by way of non-limiting example applying said principles. In the drawings:

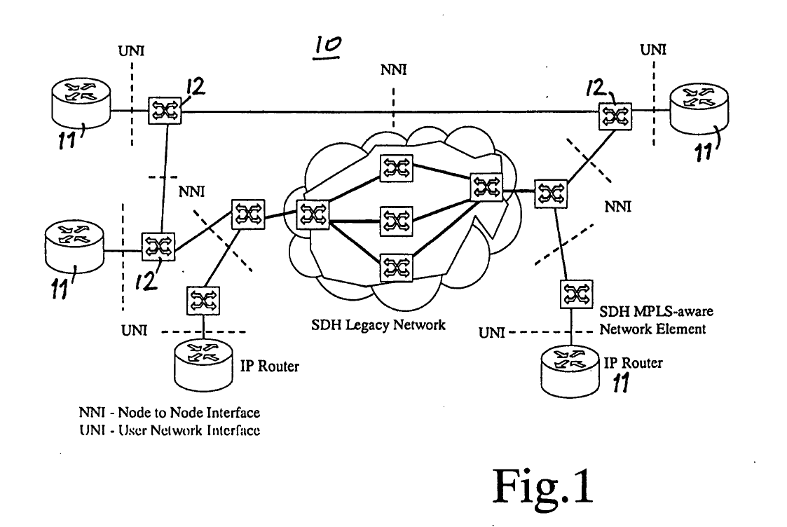

FIG. 1 shows a diagrammatic view of a network taking advantage of the principles of the present invention,

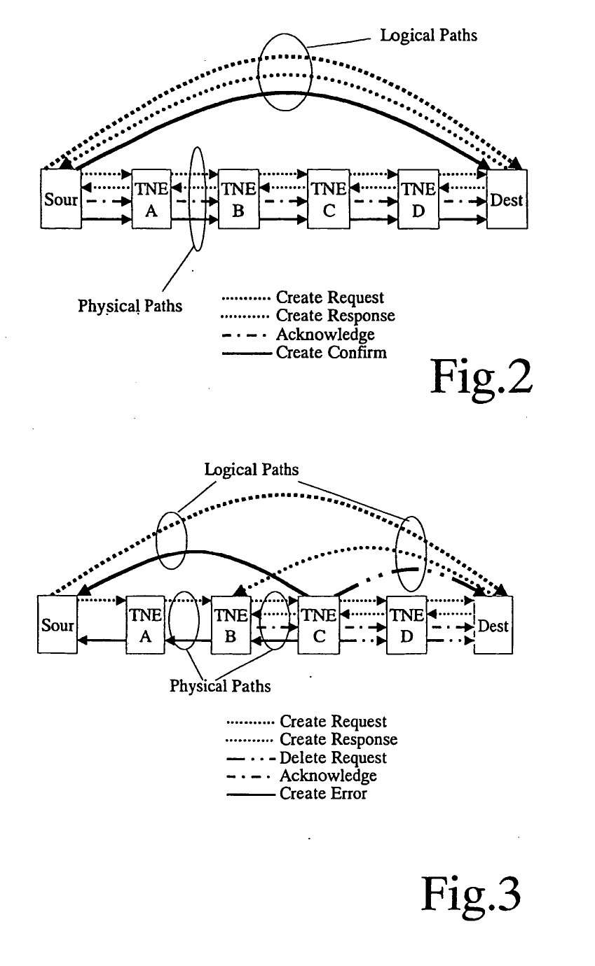

FIG. 2 shows a first flow of messages in a network in accordance with the present invention,

FIG. 3 shows a second flow of messages in a network in accordance with the present invention, and

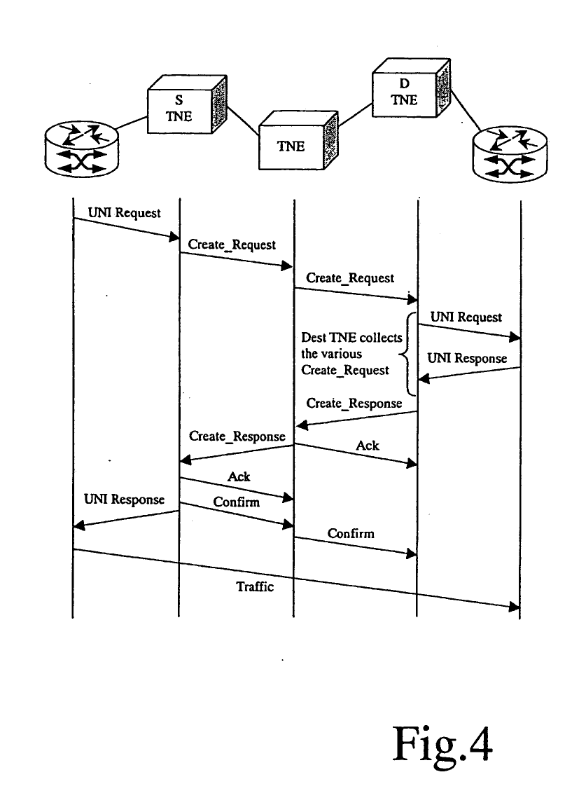

FIG. 4 shows an example of signaling for the creation of a connection in a network in accordance with the present invention.

With reference to the figures, FIG. 1 shows the diagram of a network designated as a whole by reference number 10 and made up generally of a certain number of IP Routers 11 and Network Elements (NE) 12. All the elements making up the network can be interconnected by network connections which traverse Node to Node Interface (NNI) and User Network Interface (UNI). Of course as will be clear to those skilled in the art the exact structure of the network is not binding for the use of the present invention.

The method or protocol described here is denominated ‘Light Path Control Protocol’ and for the sake of simplicity it is designated hereinafter by the initials LPCP.

As clarified below, the LPCP protocol is a simple alternative with low cost and low use of resources in place of known complex routing and signaling protocols of the PNNI or OSPF-TE/ISIS-TE type for routing and RSVP-TE or CR-LDP for signaling now being offered for optical transport networks.

LPCP is very useful for flexible allocation of SDH/SONET/lightpath circuits on requests originating from User Network Interface (UNI), Network Network Interface (NNI) and from the network management system.

Differently from the protocols based on Link State Packet such as ATM PNNI or MPLS, the LCPC protocol is based on a fully shared network database where each node keeps only its own information. This greatly reduces the computational requirements imposed on the individual node.

After reception of a connection request from the source node the LPCP protocol finds the path of least cost which satisfies the request. The request specifies the source and destination nodes and the characteristics of the path such as for example pass band, protection et cetera.

The protocol is based on a shared approach where each node knows only its own resources, the links which connect it to its neighbors and the partial results of the protocol. It knows nothing about the topology and parameters of the rest of the network. Calculation of the best path is done in shared mode where all the nodes perform one step of the calculation using their local knowledge of the network.

Provided resource allocation cost can be expressed in terms of an orderly metric the protocol can be used for any type of network or traffic engineering policy.

The node resources information includes information on the port and port characteristics (multiplexing capability), channels and their condition (operational and/or administrative) and possible internal limitations of connectivity and costs.

The information on neighbors and links includes information on the identity of neighboring nodes (IP address or a single identifier within the optical network). In addition, for each neighboring node the information includes the list of the links or SRLGs (handled differently or separately) connecting this node to the neighboring node. For each link the information includes (local node side) the basic capability of the link (the minimum band width allocable on the link group), the operational status of the link (available, unavailable), the administrative status of the link (from the GMPLS viewpoint: locked or unlocked), the cost of the link (based on the residual capability and any other parameters), the list of the permitted/prohibited user groups for the use of the link (if necessary), the index of the port/channel used for signaling the link group, and the parameters for the path creation algorithm (for example, a cost limit for propagation of the creation request).

The information on partial protocol results includes information on the request identifier, the accumulated cost and other metrics, and the preceding hop.

The protocol includes different steps for establishment of the connections. In particular there is a request step, a response step and a confirmation step.

In the request step, messages are shared throughout the network to collect information on the accumulated cost and other metrics of the possible paths. Each node stores the best partial results with the metrics of the result and the preceding hop identifying that path. These partial results are updated upon reception of a message indicating a still better path. An updating on a node is propagated to all the neighboring nodes with some exclusions. An appropriate message filtering strategy described below allows reduction of the number of messages in the network while preserving all the information necessary for finding the optimal path.

As will be seen, in the request step a timer is activated on the destination node and the expiration of this timer on the destination node and the expiration of this timer determines the end of the requested step.

Then there is the response step. The optimal path is already chosen in the preceding step and is stored in the network with hop by hop sharing information in the nodes it traverses. Starting from the destination node, a free channel is chosen towards the node indicated in the ‘preceding hop’ variable.

If the free channel is found, a matrix connection is established and the process is propagated with a response message to the preceding node of the hop. Except for the destination node, an acknowledgement message is also sent to the downstream node which sends the response message.

If on the contrary the free channel is not found, an error message is send to the source node to inform that the process has failed. In addition, a cancellation procedure is started towards the destination node to cancel the matrix connections already established.

When the last response message reaches the source node and all the matrix connections are created the circuit is established and a Confirm message is propagated from the source node to the destination node to realize the confirmation step.

To propagate the messages through the network it is necessary to establish propagation rules which must be followed by each node when a decision is required on the address of a message in the request step. The basic rules in accordance with the present invention and found beneficial at present are given below. These rules could be updated without interfering with the general behavior of the protocol in accordance with the present invention.

The main purpose of the propagation rules is to speed up the messages. Without this speeding up, the scalability of LPCP would be compromised because of the enormous amount of messages in the network.

The propagation rules mentioned below assume that the nodes can be grouped in level 1 areas with the level 1 areas being in turn grouped in level 2 areas and so on recursively up to the level N−1 areas in the level N areas.

The most suitable number N can vary according to specific requirements but for the majority of practical cases it can be 2 or 3.

In addition, the best criterion for defining the areas can also vary according to specific requirements. A suggestion could be to keep reasonably low the number of elements in an area (below one hundred) and minimize the inter-area/intra-area traffic relationship. In specific cases experimental tests which could lead to better guide lines could also be carried out.

More strictly, we can recursively define a level N area here as follows:
a node is a level 0 area, and
a level N area is a group of level N−1 areas.

Hence a level is also assigned to nodes and adjacencies. Node levels are assigned according to the criterion which demonstrates the best result in the field, for example aiming to minimize inter-area traffic.

The levels of the adjacencies on the other hand are induced by the node levels. An adjacency is at level k if it is an adjacency of a physical link and k is the minimum of the link end node levels. An adjacency is at level 0 if it is a transit adjacency.

In accordance with one aspect of the present invention propagation rules are defined as follows.
1. No propagation in the direction of the message origin.
2. No propagation of the transiting requests on a transiting adjacency.
3. No propagation on the transiting adjacency if the tail node of the adjacency is not on the same area in the destination node at the tail node level.
4. No propagation if the current and tail nodes are not in the same area as the current node.
5. No propagation if the current node level is higher than the level of the adjacency and the current and destination nodes are not in the same area at the level of the adjacency.
6. No propagation if the tail and destination nodes are not in the same area at the minimum level in which the current and destination nodes are in the same area.

Although the hierarchical partitioning concept is not entirely new in its general lines (it was used in all the main routing protocols such as for example OSPF, ISIS, PNNI), the set of propagation rules discussed above is, on the other hand, different from all the other known schemes.

Another problem is to determine the end of the request step. Indeed, one should allow the end of the request step when enough information has been collected over the network to ensure that all significant paths have been compared.

Since there is no simple and efficient way to determine how much of the network was visited by the request messages, four compromise alternatives are proposed below in accordance with one aspect of the present invention.

The first alternative calls for the use of a timer on the destination node. This is the simplest alternative; the timer is armed on the destination node when the first request message reaches that node. The timer must be set at a time at least equal to and advantageously longer than the difference between the estimated propagation times for the longest path and the shortest path from the source to the destination and the request step is terminated when the timer expires. Indeed, if the time set is at least equal to or longer than the difference between the estimated propagation times for the longest and shortest paths from the source to the destination it is highly probable that all the request messages will reach the destination node before the timer expires.

The second alternative is a finished version of the previous alternative. A timer is armed on the destination node when the first request message reaches it and the required step ends when the timer expires. But the timer is set at a time at least equal to the difference between the estimated propagation times for two paths from the source to the destination and is zeroed and restarted each time a new request message reaches the destination node.

If the time set is at least equal to and advantageously greater than the difference between the estimated propagation times for two paths from the source to the destination it is highly probable that the next request message will reach the destination node before the timer expires.

A third alternative calls for the first request message on the destination node to be immediately accepted as the best solution and the response step started. Other subsequent request messages are considered if they reach the destination node before completion of the confirmation step. If a better solution is found it is implemented and the preceding or first attempt is cancelled.

The fourth alternative can be considered an improvement on the preceding alternative. The messages are artificially delayed on each link according to the cost of the link so that the delays in arrival of the messages depend on the costs of the link they traverse. In this manner the first request message which arrives at the destination node presumably already represents the best path and no new request message is accepted in the response step.

According to one aspect of the present invention the LPCP protocol can automatically create the transits (virtual adjacencies). The LPCP protocol was conceived for controlling a stratified transport network. The conventional operation of stratified networks assumes configuration of the server layers before configuration of the client layers. If a circuit is required at a client layer and there is no connectivity, creation of the circuit must be suspended until additional links are created in the form of circuits in the server layer.

LPCP also allows a more intelligent and integrated way of operation in which the search for a route takes all the layers into consideration. Selection of a link in a layer of a higher order naturally has a higher cost because it occupies a greater band width.

This way LPCP automatically creates transits when necessary and these transits are thus available for other circuits. Cancellation of a transit created automatically is also automatic and takes place when all the client layer circuits used are cancelled.

The behavior of the automatic creation of a transit in accordance with the present invention is described below.

In the response step, messages are made to flow over the entire network without regard for the capability of a node to be connected with the requested granularity. If the node has coarse grained matrix connection capability this fact is expressed only in the cost associated with the links.

In the response step the selected matrix connections are realized. If some connections have a coarser grain than that of the required circuit they are declared to be part of a transit and the transit is declared and created with its own identifier which is different from that of the circuit.

Each transit creates its own confirmation step. The Confirm message is propagated between the two ends of the transit which, in general, will not coincide with the destination and source nodes of the required circuit.

The presence of a transit between two nodes is notified to these nodes as a new adjacency. This will be use by subsequent LPCP activations.

To clarify the innovative principles or the present invention FIGS. 2 and 3 show message flows in the connection process.

First of all, as mentioned above, various message types are defined each with its own propagation direction.

The messages and propagation directions are summarized in the following table.

| Description of message | Direction of message |
|---|---|
| LPCP Create Request | Source → Destination |
| LPCP Create Response | Destination → Source |
| LPCP Create Confirm | Source → Destination |
| LPCP Acknowledge | TNE upstream → TNE Downstream |
| LPCP Create Error | TNE → Source |
| LPCP Delete Request | Source → Destination |
| LPCP Delete Response | Destination → Source |

In the definition of direction ‘Source/destination’ means that the message traverses all the associated Transit Network Elements, TNEs in the source/destination direction for that particular connection request.

FIG. 2 shows the flow of messages in an LPCP enabled network in case of success in the creation.

FIG. 3 shows the case of failure in the creation supposing that the TNE C aborts the procedure and therefore sends a Delete Request to the destination node and a Create-Error message to the source node.

In both FIGS. 2 and 3 the physical paths between the network elements and the corresponding logical paths between the terminal nodes are shown (source node and destination node in case of success or nodes involved in the generation of messages in case of failure).

FIG. 4 shows an example of creation of a circuit with the representation of the creation signaling sequence.

In particular, there are the following steps in the example.
1. The UNI-C requires a connection to the boundary TNE.
2. The TNE emits a Create_Request.
3. The intermediate TNE propagates the Create_Request in accordance with the rules explained above.
4. The destination TNE sends a UNI request to the destination client.
5. The destination client accepts the entering request. In the contrary case the signaling process ends here and a connection request refusal message is sent over the source client.
6. If all the useful Create_Request messages have arrived (how this decision on the arrival of all the messages might be made has already been explained) the destination TNE generates and propagates the Create_Response message over the selected path.
7. The intermediate nodes propagate the Create_Response message and send a Confirm message (Ack) to the preceding node. The Confirm message (Ack) could also carry an error message.
8. The source TNE informs the source client and sends the Confirm message over the destination TNE.
9. The source client starts sending traffic.
10. The Confirm message reaches the destination TNE.

It is now clear that the predetermined purposes have been achieved.

A unique characteristic of LPCP is that it can find optimal paths without distribution to all the network equipment on the topology and restriction data. Each network element only has to keep its own data and some surrounding information and thus drastically reduces the quantity of data which must be copied and stored in the network element.

Copying onto the network with LPCP takes place only at the time of the UNI request while with OSPF and other LSP routing protocols the copying takes place upon any event which significantly changes the network topology and on a periodic basis. As may be seen, every request to establish a path or eliminate it ‘significantly’ changes the network topology in the real transport networks so that LPCP has an advantage as compared to OSPF and other routing protocols based on copying of the link status information.

In addition LPCP doesn't need to warn all the equipment in the network or in its area of the unavailability of the resources involved since the equipment involved is immediately aware of the problem. It will use this knowledge only at the time a new circuit is required.

Naturally the above description of an embodiment applying the innovative principles of the present invention is given by way of non-limiting example of said principles within the scope of the exclusive right claimed here. For example, as readily imaginable by those skilled in the art, the LPCP protocol is also expandable for the purpose of obtaining functionality such as broadcast connections, protected connections using SNCP and protected connections using preplanned software repair (end-to-end or local-repair). Of course, the protocol proposed here is capable of supgateing different kinds of connection capability such as for example one-way and two-way point to point connections.

1-30. (canceled)

31. A telecommunications network control method of finding optimal paths in a network between source and destination nodes and of establishing connections through said paths, the method comprising a request step, a response step, a confirmation step, and a step of propagating request step messages over the network to collect information about accumulated cost and other metrics of possible paths, each node reached by the request step messages storing best partial results with the metrics to form a result, and a preceding hop identifying an optimal path based on said result so that knowledge of the network by the node is unnecessary.

32. The method in accordance with claim 31, and updating said partial results upon reception of a new request step message indicating a still better path, propagating an updating on a node to all possible neighboring nodes with some exclusions, choosing the optimal path in the request step, and storing in the network with hop-by-hop sharing information in the nodes which are traversed.

33. The method in accordance with claim 32, in which starting from the destination node, choosing a free channel towards the node indicated in a variable preceding hop, and then performing the response step by finding a free channel and establishing a matrix connection, and propagating a response message to a preceding node of the hop.

34. The method in accordance with claim 33, in which except for the destination node, sending an acknowledgment message to a downstream node which sends a response message.

35. The method in accordance with claim 34, in which when the response message believed to be the last reaches the source node, and all the matrix connections are created, a circuit is established, and a confirmation message is propagated from the source node to the destination node to complete the confirmation step.

36. The method in accordance with claim 35, in which if the free channel is not found, sending an error message to the source node to inform that the process failed, and starting a cancellation procedure towards the destination node to cancel matrix connections already established.

37. The method in accordance with claim 31, in which the request step is performed by activating a timer for a predetermined time on the destination node, and determining an end of the request step upon elapse of the predetermined time of the timer on the destination node.

38. The method in accordance with claim 37, and arming the timer on the destination node when the first request message reaches that node, and setting the predetermined time to be at least equal to a difference between estimated propagation times for a longest path and a shortest path from the source node to the destination node.

39. The method in accordance with claim 37, and arming the timer when a first request message reaches the destination node, and setting the predetermined time to be at least equal to a difference between estimated propagation times for two paths from the source node to the destination node, and resetting the timer to said predetermined time, and restarting the timer for each request message reaching the destination node.

40. The method in accordance with claim 31, and accepting the first request message which reaches the destination node as the best solution, starting the response step, considering other subsequent request messages if they reach the destination node before completion of the confirmation step, implementing a better solution if it is discovered, and canceling the preceding or first attempt.

41. The method in accordance with claim 31, and artificially delaying the request step messages on each path traversed in the network according to the cost of the path, and accepting the first request message reaching the destination node as representing the optimal path.

42. The method in accordance with claim 31, and setting message propagation rules by grouping the network nodes in level 1 areas, grouping the level 1 areas in level 2 areas, and continuing recursively up to the level N−1 areas in the level N areas.

43. The method in accordance with claim 42, in which the number N is 2 or 3.

44. The method in accordance with claim 42, and defining the areas so as to keep low the number of elements in an area, to minimize an inter-area/intra-area traffic relationship.

45. The method in accordance with claim 42, and defining a level N area recursively by assigning a node as a level 0 area, and a level N area as a group of level N−1 areas.

46. The method in accordance with claim 42, in which in addition to the nodes, a level is also assigned to the adjacencies, and the levels of the adjacencies are induced by the node levels by observing that an adjacency is at level k, if it is a physical link adjacency, and k is a minimum between the end node levels of the link, and an adjacency is at level 0 if it is a transiting adjacency.

47. The method in accordance with claim 31, and defining levels and areas for the nodes and adjacencies, and setting the following message propagation rules:
no propagation in a direction of the message origin;
no propagation of requests transiting on a transiting adjacency;
no propagation on the transiting adjacency if a tail node of the adjacency is not in the same area in the destination node at a tail node level;
no propagation if the current and tail nodes are not in the same area at a current node level;
no propagation if the current node level is higher than the level of the adjacency, and the current and destination nodes are not in the same area at the level of the adjacency; and
no propagation if the tail and destination nodes are not in the same area at the minimum level in which the current and destination nodes are in the same area.

48. The method in accordance with claim 47, and implementing at least the following messages with the below listed associated propagation directions:

| Description of Message | Direction of Message |
|---|---|
| LPCP Create Request | Source → Destination |
| LPCP Create Response | Destination → Source |
| LPCP Create Confirm | Source → Destination |
| LPCP Acknowledge | TNE upstream → TNE Downstream |
| LPCP Create Error | TNE → Source |
| LPCP Delete Request | Source → Destination |
| LPCP Delete Response | Destination → Source |

49. The method in accordance with claim 48, in which when creating a connection is requested from a boundary TNE node, performing the following sequence of events during a signaling sequence for the creation of the connection:
the TNE emits a Create Request;
the intermediate TNE nodes propagate the Create Request;
the destination TNE sends a UNI request to a destination client;
if the destination client accepts the entering request, the process continues, or in case of refusal, the signaling process ends, and a connection request refusal message is sent over a source client;
if the process continues, when all the useful Create Request messages have arrived, the destination TNE generates and propagates the Create Request message over the selected path;
the intermediate nodes propagate the Create Response message and send a Confirm message (Ack) to the preceding node;
the source TNE informs the source client and sends the Confirm message over the destination TNE;
the source client starts sending traffic; and
the Confirm message reaches the destination TNE.

50. The method in accordance with claim 31, in which, in the request step, messages are made to flow over the network without regard for the capability of a node to connect with the required granularity, and if the node has coarse grain matrix connection capability, this fact is expressed only in the cost associated with the corresponding paths.

51. The method in accordance with claim 50, in which, in the response step, selected matrix connections are realized, and if some connections have a grain coarser than that of the requested circuit, they are declared to be part of a transit.

52. The method in accordance with claim 51, and declaring the transit and creating the transit with its own identifier which is different from that of the circuit.

53. The method in accordance with claim 51, in which each transit realizes its own confirmation step, and propagating the associated confirmation message between two ends of the transit.

54. The method in accordance with claim 51, and notifying the presence of the transit between two nodes to these nodes as a new adjacency.

55. The method in accordance with claim 31, in which connection request messages from the source node specify the source and destination nodes and characteristics of the path.

56. The method in accordance with claim 31, in which the nodes possess information on resources of the node which include information on ports and characteristics of the ports, channels, channel status and internal limitations of connectivity and costs.

57. The method in accordance with claim 31, in which the nodes possess information on neighbor nodes and paths which include information concerning identity of the neighboring nodes.

58. The method in accordance with claim 57, in which for each neighboring node, the information also includes a list of paths connecting this node to the neighboring node, and for each link, the information includes capability of the path, operational status of the path, administrative status of the path, and the cost of the path.

59. The method in accordance with claim 31, in which the information on the partial results include information on an identifier of the request, the accumulated cost and other metrics and the preceding hop.

60. A telecommunications network implementing the method in accordance with claim 31.
